(19) United States
(12) Patent Application Publication
(10) Pub. No.: US 2010/0208261 A1
(43) Pub. Date: Aug. 19, 2010

(54) SPECTROMETER WITH LED ARRAY

(75) Inventors: Ruediger Sens, Ludwigshafen (DE); Christos Vamvakaris, Mannheim (DE); Wolfgang Ahlers, Nossegem (BE); Erwin Thiel, Siegen (DE)

Correspondence Address: OBLON, SPIVAK, MCCLELLAND MAIER & NEUSTADT, L.L.P., 1940 DUKE STREET, ALEXANDRIA, VA, 22314, US

(73) Assignee: BASF SE, Ludwigshafen (DE)

(21) Appl. No.: 12/680,847

(22) PCT Filed: Oct. 8, 2008
(86) PCT No.: PCT/EP08/63443

§ 371 Date: Mar. 30, 2010

(30) Foreign Application Priority Data
Oct. 11, 2007 (EP) 07118257.0

(51) Int. Cl. G01J 3/28; H01L 31/12; H01J 40/14; G01N 21/59; G01N 21/55; G01J 1/58

(52) U.S. Cl. 356/326; 257/84; 250/216; 356/432; 356/445; 250/458.1; 257/E33.077

(57) ABSTRACT

A device (110) for determining at least one optical property of a sample (112) is proposed. The device (110) comprises a tuneable excitation light source (114; 410) for applying excitation light (122) to the sample (112). The device (110) furthermore comprises a detector (128, 130; 312) for detecting detection light (132, 136; 314) emerging from the sample (112). The excitation light source (114; 410) comprises a light-emitting diode array (114), which is configured at least partly as a monolithic light-emitting diode array (114). The monolithic light-emitting diode array (114) comprises at least three light-emitting diodes (426) each having a different emission spectrum.

The invention relates to a device for determining at least one optical property of a sample. Furthermore, the invention relates to a method for identifying whether a product is a branded product or a counterfeit of a branded product, and to a method for determining at least one optical property of a sample. Such devices and methods are generally used in chemical analysis, environmental analysis, medical technology or in other areas. A specific main emphasis of this application is on devices and methods which are used for protection against product piracy.

The prior art discloses numerous devices for determining at least one optical property of a sample, which are usually embodied in the form of spectrometers. Such spectrometers usually have a light source for generating a tuneable light beam and at least one detector. Said at least one detector is designed to pick up light reflected, scattered, transmitted or emitted in the form of luminescence light (that is to say phosphorescence light and/or fluorescence light) from the sample. Spectroscopy methods are known in which the excitation light radiated onto the sample is spectrally tuned, and spectroscopy methods are known in which the light emerging from the sample, for example through light, fluorescence light, phosphorescence light, reflection light or scattered light, is picked up in a spectrally resolved manner.

Such spectrometers are accordingly generally designed in such a way that they have optical separating devices in order to spectrally separate the excitation light radiated onto the sample and/or the detection light emerging from the sample. Thus, by way of example, a white light source can be used as an excitation light source, wherein, in order to alter the wavelength of the excitation light, the light emerging from said white light source is decomposed into its spectral components by a monochromator (for example a prism and/or an optical grating) in order then to select from these spectral components a specific wavelength or a wavelength range as excitation wavelength and to radiate it onto or into the sample. Such a spectrum in which the wavelength radiated in is tuned is often also referred to as an excitation spectrum.

Analogously, on the detection side, the detection light emerging from the sample can be spectrally split by an optical separating device in order to record a detection light spectrum.

The devices for spectrally separating light which are used in these known spectrometers are extremely complicated in practice, however. Thus, prism spectrometers, in particular, and also spectrometers which operate using an optical grating require a large amount of space since minimum propagation paths of the light beams and also a suitable mechanism are required for reliable separation. Moreover, such optical separating devices are in practice extremely sensitive to vibration and therefore not very suitable for use for example in mobile units, in particular handheld units.

A further possibility for providing a tuneable light source for a spectrometer device of this type would consist in making the light source itself tuneable. However, to date only a small number of light sources are known which are tuneable as such, that is to say can optionally emit light in at least two wavelength ranges. A crucial example for the art of such tuneable light sources is tuneable lasers, which exist in various technical embodiments. Thus, by way of example, specific types of solid-state lasers, dye lasers and diode lasers are generally tuneable with a limited wavelength range. What is disadvantageous about these devices, however, is that such tuneable lasers are generally likewise extremely sensitive to vibrations, electromagnetic influences, temperature influences or contamination, that a considerable technical outlay is required for the operation of such lasers, and that the wavelength range over which the excitation light can be tuned is generally severely limited. These disadvantages, too, have the effect that lasers are largely unsuitable as excitation light sources for handheld units, in particular handheld units of the type described above for protection against brand piracy.

Therefore, it is an object of the present invention to provide a device for determining at least one optical property of a sample which avoids the disadvantages of the devices known from the prior art. In particular, the device is intended to make it possible to check whether a product is a branded product or a counterfeit of a branded product. The device is, however, intended to be usable in other areas, too, in particular in areas in which mobile handheld units are required.

This object is achieved by means of a device having the features of claim 1. Advantageous developments of the device, which can be realized individually or in combination, are represented in the dependent claims. All of the claims are hereby incorporated in the content of the description.

A device is proposed which comprises a tuneable excitation light source for applying excitation light to the sample, in particular radiating said sample with excitation light. Furthermore, the device is intended to comprise a detector for detecting detection light emerging from the sample. In order to avoid the above-described problems which occur in connection with known excitation light sources for devices of this type, the invention proposes that the excitation light source comprises a light-emitting diode array. Said light-emitting diode array is configured at least partly as a monolithic light-emitting diode array, wherein the monolithic light-emitting diode array comprises at least three light-emitting diodes each having a different emission spectrum.

In this case, “monolithic” should be understood to mean a component which is not composed of individual parts (that is to say individual light-emitting diodes), but rather is essentially produced in a common production process on an individual carrier (that is to say for example an individual chip, if appropriate with additional individual parts). In particular, the monolithic light-emitting diode array can have an inorganic monolithic light-emitting diode array having an inorganic semiconductor chip and/or an organic monolithic light-emitting diode array. Such organic monolithic light-emitting diode arrays, in which a plurality of organic light-emitting diodes (that is to say for example light-emitting diodes having a polymer and/or a low-molecular-weight organic emitter and/or further organic layers such as, for example, organic n-semiconducting or p-semiconducting layers) are provided, can preferably be provided with corresponding thin-film transistor circuits (for example active matrix circuits) integrated on the carrier. As an alternative or in addition, it is also possible, of course, to integrate on the carrier further components such as, for example, electronic driving components for the modulated excitation of the light-emitting diodes (see below). Corresponding circuits such as, for example, transistor circuits for driving the light-emitting diodes can also be provided on an inorganic semiconductor chip with a light-emitting diode array.

In the present case, an “array” is to be understood here to mean an arrangement of light-emitting diodes which comprises at least three light-emitting diodes. It is preferred, however, in order to provide a highest possible number of “support points” for recording a spectrum, if the light-emitting diode array comprises at least four, particularly preferably ten, light-emitting diodes or even one hundred light-emitting diodes or more.

It has become possible in the meantime for light-emitting diode arrays of this type to be realized technically as monolithic components and they can be produced for example by means of a suitable mask technique in parallel methods or using serial method technology, such that for example differently doped light-emitting diodes or light-emitting diodes which are each based on a different emitter material (e.g. a different inorganic semiconductor material or a different organic emitter) can be produced alongside one another on a semiconductor chip. By way of example, the light-emitting diode array can comprise a rectangular or square matrix of regularly arranged light-emitting diodes, or else irregular arrangements.

Each individual one of these light-emitting diodes preferably has a fixed spectral width. It is preferred here if light-emitting diodes are used which inherently have a spectral width (preferably the full width at half maximum, FWHM) of not more than 30 nm, preferably even of not more than 20 nm. A light-emitting diode array which covers a spectral width of 450 nm to 850 nm is preferably used. Partial regions of this essentially visible spectrum can also be realized, however, and are beneficial in practice, depending on the application.

The light-emitting diode array can furthermore be improved, in particular for practical use in portable units, if the light-emitting diodes are temperature-regulated, that is to say kept at an essentially constant temperature. For this purpose, a temperature-regulating device can be provided, for example, which is designed to regulate the temperature of the light-emitting diode array. This temperature-regulating device can comprise one or a plurality of Peltier elements, for example, which can be used to cool the light-emitting diode array, for example. In this way, the spectral properties can be kept constant by the temperature regulation even in the case of the light-emitting diode array being subjected to loading and/or in the case of a changing ambient temperature. Other types of temperature regulation are also possible in principle, however, for example by means of liquid temperature regulation. The temperature-regulating device can comprise in particular a regulation device for setting an operating temperature, for example a regulation device having one or a plurality of temperature sensors for detecting the current temperature of the light-emitting diode array.

As described above, many spectrometer devices known from the prior art have one or two or even more monochromators, i.e. optical separating devices, which are unwieldy for practical use. In the case of the device according to the invention by contrast, the principle of the tuneable light source, analogously for example to a tuneable laser, is used, that is to say a principle wherein the excitation light source itself is variable in terms of its spectral emission properties. By way of example, the individual light-emitting diodes of the light-emitting diode array can be used successively, for example by sequential switching-on. A mixture by varying the individual intensities of the light-emitting diodes is also possible. The device can be configured for example in such a way that the light-emitting diodes of the light-emitting diode array lie so close together that if all the light-emitting diodes of the light-emitting diode array are switched on, essentially a mixed light beam arises. For this purpose, the light-emitting diodes can have for example an average spacing (pitch) which is less than one millimetre, preferably less than 800 micrometres, and particularly preferably less than 600 micrometres. In an arrangement of this type, the individual emissions of the light-emitting diodes of the light-emitting diode array are essentially combined to form a common excitation light beam.

As an alternative or in addition, however, it is also possible to provide a combination device which utilizes the reversibility of the light path and combines the individual emissions of the light-emitting diodes to form a common excitation light beam. By way of example, said combination device can comprise a prism and/or a wavelength-selective mirror (for example a dichroic mirror) and/or an optical grating or a fibre bundle, wherein the individual light beams of the light-emitting diodes are brought together by means of these devices and combined to form a common excitation light beam. In this way, within the spectral width made available by the light-emitting diodes, an excitation light beam having desired spectral properties can be assembled by corresponding driving (that is to say for example switching on and off or setting of the light intensity) of the individual light-emitting diodes.

On the detection side, too, as an alternative or in addition, it is possible to provide an optical separating device which spectrally decomposes the detection light into at least two wavelength ranges. It is possible once again to provide prisms, wavelength-selective mirrors, dichroic mirrors, optical gratings or similar devices. In this context or independently thereof, the detector can comprise for example a detector array having at least two individual detectors, such that for example different wavelength ranges can be imaged onto separate detectors. By way of example, photodiode arrays of monolithic configuration can again be used for this.

Thus, the detector can have for example at least one luminescence light detector arranged non-collinearly with the excitation light and/or a transmission light detector arranged collinearly with the excitation light and/or a reflection light detector for detecting excitation light reflected from the sample. Various arrangements of this type are possible and are described in part by way of example below.

A control device, in particular, can be provided for driving the device. A control device of this type can comprise for example a microcomputer and/or further electronic components and can be realized wholly or partly as a computer program. By way of example, the control device can comprise a microcomputer, if appropriate with volatile and/or non-volatile memory elements and input and output means. Said control device can be designed, in particular, to generate an excitation light having predetermined spectral properties for driving the individual light-emitting diodes (for example by choosing a corresponding diode current for each individual light-emitting diode) of the light-emitting diode array.

In order to record a spectrum by means of the proposed device in one of the embodiments described above, for example the individual light-emitting diodes can be driven sequentially in order, in this way, to spectrally tune the excitation light and in each case to record the detection light. In one preferred embodiment of the invention, however, a multiplexing device is provided, which enables parallel recording of a plurality or all of the spectral components instead of a time-consuming sequential recording method. For this purpose, the multiplexing device can be designed to modulate at least two of the light-emitting diodes of the light-emitting diode array with different modulation frequencies. Thus, in particular the intensity of the individual light-emitting diodes can be varied, for example in sinusoidal or cosinusoidal fashion or in some other periodic excitation form (for example a sawtooth pattern, a rectangular pattern or the like). In the case of light-emitting diodes, such modulation can be effected for example by modulation of the diode current, wherein in many cases the light intensity of the light emitted by the individual light-emitting diodes follows the diode current proportionally or in a known relationship.

Such a modulation of the individual light-emitting diodes, wherein preferably all of the light-emitting diodes are modulated with different modulation frequencies, enables for example a spectral analysis of the detection signal in a very short time and/or a lock-in method for recording a spectrum. In this way, in particular the signal-to-noise ratio of the signal recorded by the device and/or of the spectra recorded by the device can be considerably improved. This last can also be referred to as a “multiplex advantage”.

Parallel recording of a spectrum can be realized in particular by virtue of the fact that, analogously to the known lock-in technique, the control device furthermore has a demodulation device, wherein the demodulation device is designed to demodulate detection light phase-sensitively and/or frequency-sensitively and to assign it in each case to one of the modulated light-emitting diodes. In this way, whilst avoiding sequential “tuning” of the light source, detection light components of simultaneously recorded detection light can be spectrally separated and a spectrum can thus be recorded within a very short time. Such recording of a spectrum can therefore be effected within fractions of a second, which in turn becomes apparent extremely advantageously in particular for use in a handheld unit. In the case of a handheld unit, for example a handheld unit placed manually on a surface of a sample to be examined, customary spectroscopy methods generally cannot be used owing to shaking of the hand and the associated alterations of the sample. A hand spectrometer that supplies a spectrum within seconds is suitable for this purpose, by contrast.

Thus, the device can be configured as a mobile handheld unit and can furthermore comprise a housing comprising an opening for introducing a liquid cuvette with a liquid or gaseous sample, an opening for introducing a solid sample, an opening for applying the excitation light to a sample situated outside the housing and for picking up the detection light, and also further components, if appropriate. The housing can also preferably contain the control device described above. A mobile handheld unit of this type can advantageously be used in chemical analysis, medical technology (for example in the area of medical diagnosis) and in the area of “brand protection” (protection against brand and product piracy) described above.

Preferably, a handheld unit of this type furthermore has at least one interface for connection to a mobile data transmission unit and/or a computer, for example a wire-based and/or a wireless interface, such as, for example, a Bluetooth interface or the like. A data transmission device for wireless data transmission can also be provided as an alternative or in addition, for example a data transmission device for transmitting data in a mobile radio network. In this way it is possible for example to use methods wherein a tester checks on site a relatively larger quantity of goods by means of the device, transmits the results to a central computer (for example a laptop and/or via a mobile radio network to a central computer), wherein in the handheld unit itself and/or in the central computer (for example by comparison with known spectra) it is possible to ascertain whether the product currently being tested is an approved (i.e. for example licensed) product of an authorized manufacturer or is a counterfeit. A feedback signal from a central computer to the mobile handheld unit can correspondingly also be effected, said signal comprising the result of the comparison. As an alternative or in addition, however, the evaluation can also be effected wholly or partly on the mobile handheld unit itself.

A method is correspondingly proposed which involves checking whether the product is a branded product (that is to say a specific product from a specific manufacturer) or a counterfeit of a branded product, wherein the branded product has at least one characteristic optical property. In this case, the device in one of the embodiments described above is used to test whether said product has a characteristic optical property. The characteristic optical property can be for example once again a fluorescence property, a phosphorescence property, an absorption property, a reflection property, a scattering property or a combination of these or other properties. By way of example, it is possible to search in a targeted manner for dyes used in a company logo (which dyes may in part also be invisible to the human eye), for example for specific fluorescence properties.

It is particularly preferred in this case if the branded product comprises a mineral oil product. By way of example, a marker dye which can be identified spectroscopically in a targeted manner can be admixed with such mineral oil products. Counterfeit products which do not have said marker dye can be identified rapidly and reliably in this way by means of the handheld unit proposed. In this case, the marker dye can be admixed separately as a dye or pigment, or, as an alternative or in addition, can also consist in the form of a marker group bonded (e.g. by chemical or physical bonding) to a molecule of the product. Other forms of marking are also possible and known to the person skilled in the art.

For evaluation purposes it is possible to use correlation methods, for example, wherein spectra recorded by means of the handheld unit and/or by means of some other configuration of the device described above are compared with known spectra, in particular reference spectra. In this way, a corresponding statement about the presence or non-presence of a counterfeit or a counterfeit product can be made rapidly and reliably.

Further details and features of the invention will become apparent from the following description of preferred exemplary embodiments in conjunction with the dependent claims. In this case, the respective features can be realized by themselves or as a plurality in combination with one another.

The invention is not restricted to the exemplary embodiments. The exemplary embodiments are illustrated schematically in the figures. In this case, identical reference numerals in the individual figures designate elements that are identical or fractionally identical or correspond to one another with regard to their functions.

In detail:

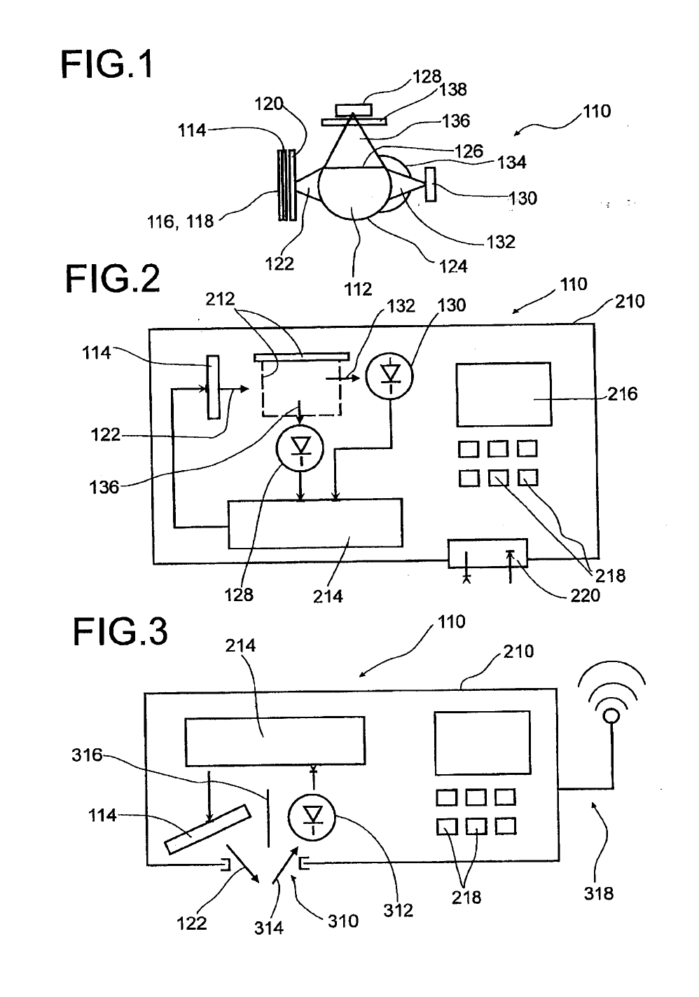

FIG. 1 shows a basic schematic diagram of a device according to the invention;

FIG. 2 shows a schematic illustration of the device in a configuration as a handheld unit for absorption and fluorescence measurements;

FIG. 3 shows a schematic illustration of a configuration of the device as a handheld unit for reflection measurements;

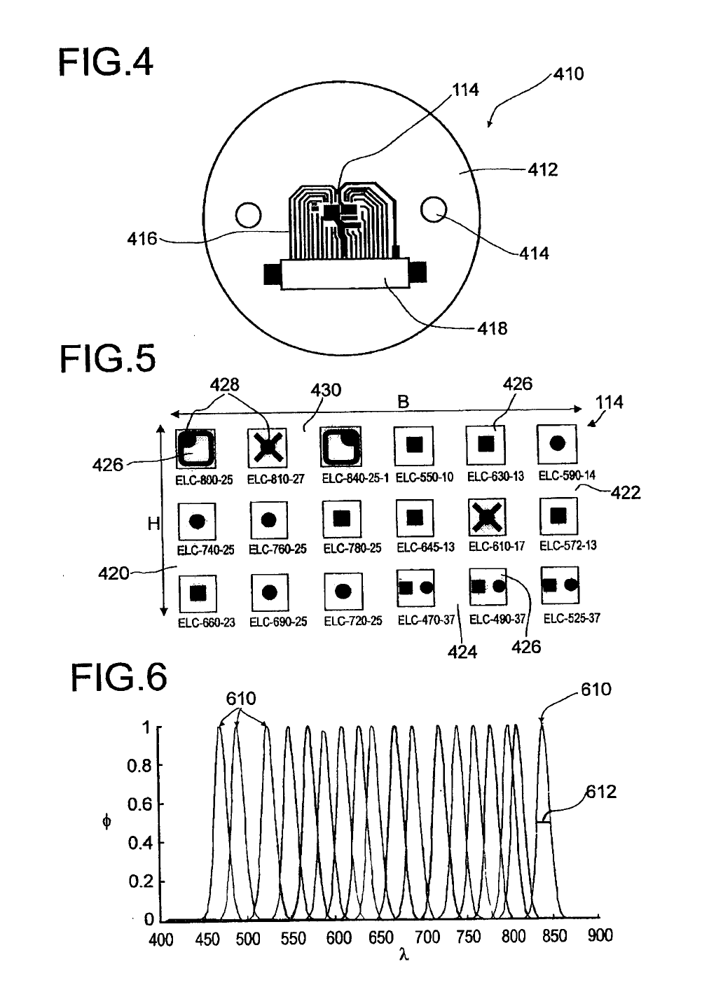

FIG. 4 shows a schematic illustration of a plan view of an excitation light source according to the invention with an LED array chip;

FIG. 5 shows an enlarged illustration of the LED array chip;

FIG. 6 shows an illustration of the emission spectra with the individual LEDs of the LED array chip in accordance with FIG. 5;

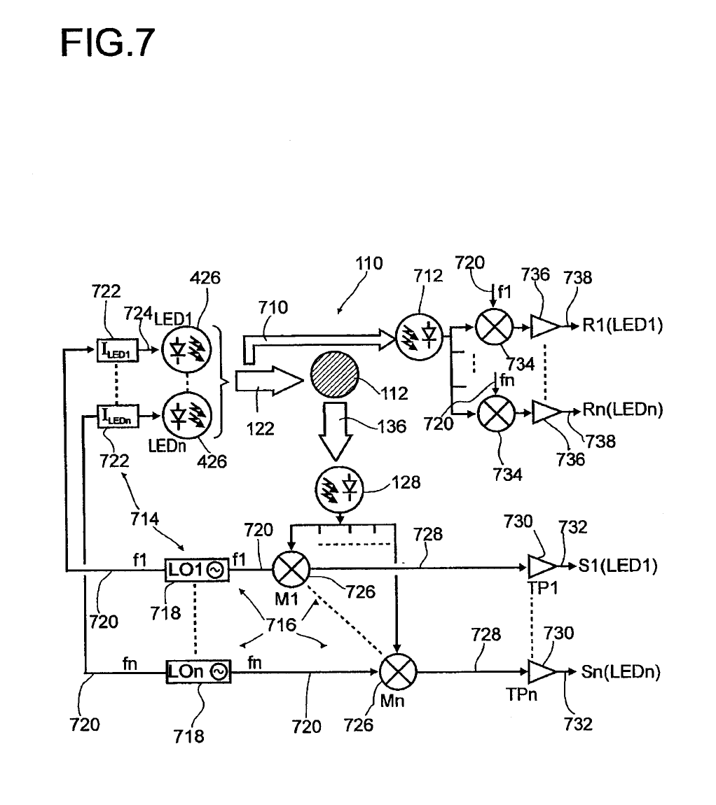

FIG. 7 shows a schematic illustration of a configuration of the device with a multiplexing device and a demodulation device;

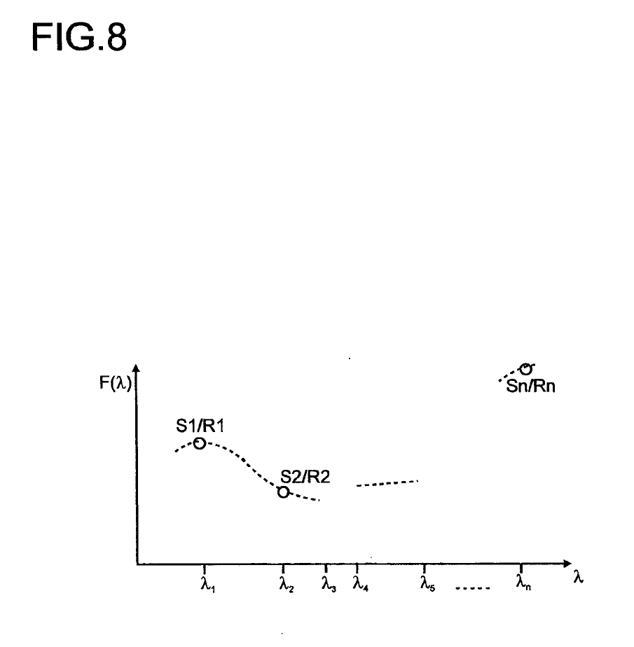

FIG. 8 shows a schematic illustration of the creation of a spectrum from the measurement data obtained by means of the device in FIG. 7;

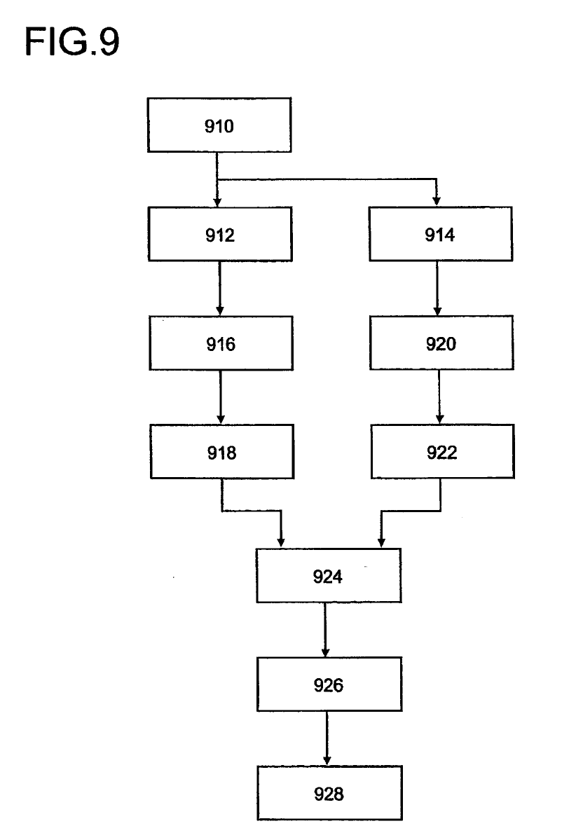

FIG. 9 shows a possible flowchart of a method according to the invention;

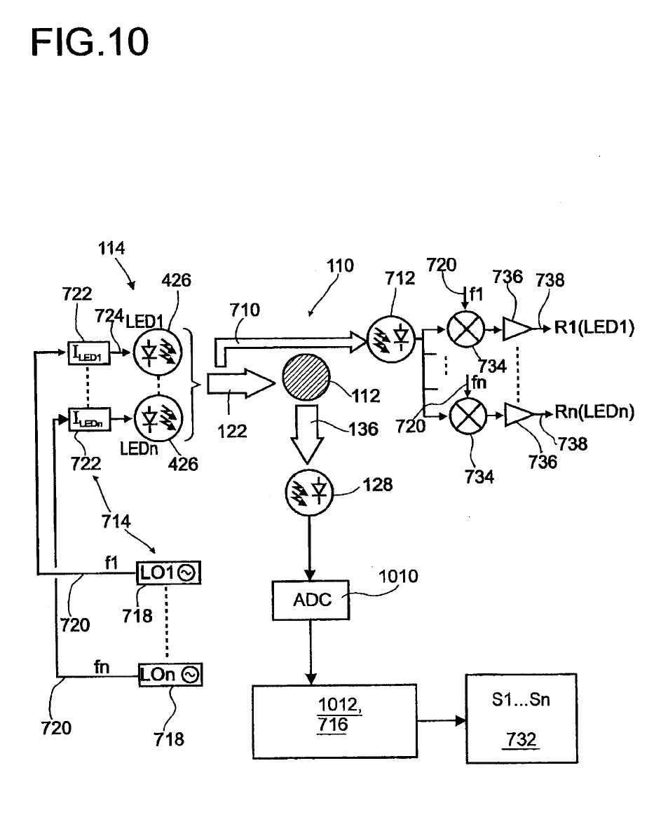

FIG. 10 shows a schematic illustration of a modification of the device in accordance with FIG. 7; and

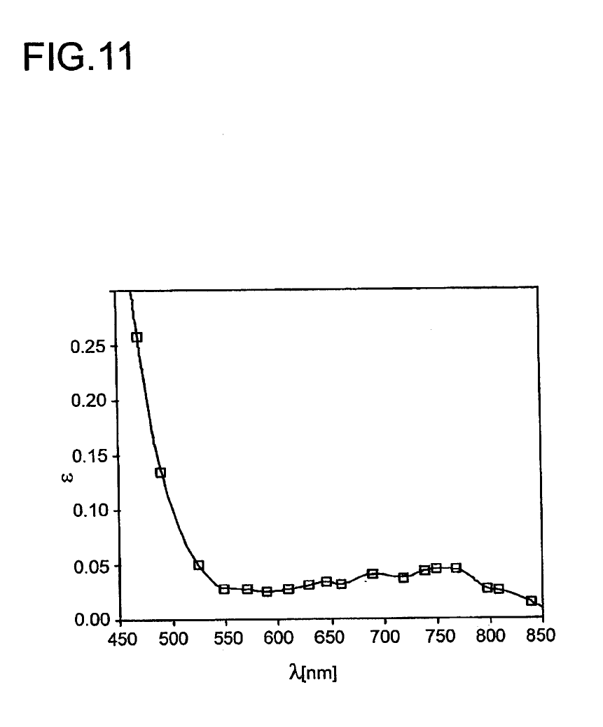

FIG. 11 shows an example of a spectral measurement of a mineral oil marked with a marker substance with a device in accordance with FIG. 2.

FIG. 1 illustrates a schematic illustration of an exemplary embodiment of a device 110 according to the invention for determining at least one optical property of a sample 112. In this simple exemplary embodiment, the device 110 comprises a monolithic light-emitting diode array 114 (hereinafter also called LED chip) applied on an aluminium carrier 116. The aluminium carrier 116 is applied by means of a Peltier element 118 (illustrated integrally with the aluminium carrier in FIG. 1). In this exemplary embodiment, the Peltier element 118 acts as a temperature-regulating element for regulating the temperature of the LED chip 114.

A monitor 120 is optionally introduced into the device 110 in front of the LED chip 114 in order to visualize an excitation light beam 122 generated by the LED chip 114. The monitor 120 serves for detecting the excitation light intensity emitted by the LED chip 114 and enables for example a mathematical correction of the excitation light source.

The excitation light beam 122 is radiated into the sample 112, which is liquid in this exemplary embodiment and which is accommodated in a cuvette 124. Said cuvette 124 is provided with an essentially circular cross section, with a flattened portion 126 in a direction perpendicular to the direction of incidence of the excitation light beam 122. Furthermore, the device 110 in accordance with the exemplary embodiment in FIG. 1 has two detectors 128, 130. Thus, a first detector 128 is arranged collinearly with the excitation light beam 122 and can be used for example for absorption measurements. Said detector 130 can for example also be configured as an array or diode line of photodiodes or photo cells and serves for detecting transmitted detection light 132. Furthermore, in the exemplary embodiment illustrated in FIG. 1, a planastigmatic correction 134 for astigmatism correction is arranged in the beam path of said transmission light 132. Said planastigmatic correction 134 has the task of correcting astigmatic distortions that can be caused in particular by round samples.

In the exemplary embodiment illustrated in FIG. 1, a second detector 128 is arranged with a viewing direction perpendicular (or else in a viewing direction that differs from 90°, for example 60°-89°) to the excitation light beam, such that detection light in the form of fluorescence light 136 which leaves the sample 112 perpendicular to the direction of incidence of the excitation light beam 122 can be detected by said detector 128. One or a plurality of filters 138 can optionally also be provided between the detector 128 and the sample 112.

The device 110 illustrated in FIG. 1 can be embodied with very small dimensions, in principle, and, including corresponding driving and evaluation electronics, can be for example of the size of a mobile radio telephone.

FIGS. 2 and 3 schematically show devices 110 which integrate such a construction in accordance with FIG. 1 or in accordance with a modification of the device in FIG. 1 in a housing 210. By way of example, said housing 210 can have dimensions which do not exceed 20 cm in each case in width and height and do not exceed 5 cm in depth. By way of example, said housing 210 can be produced from a plastic, for example a polypropylene or a similar plastic, such that the device 110 is configured as a handheld unit and can be kept conveniently in a pocket, for example, for use in the field.

The device 110 in FIG. 2 again has a light-emitting diode array 114 as an excitation light source, which, since the individual light sources of the light-emitting diode array 114 lie very close together (see below), essentially generates an individual excitation light beam 122. The sample 112 is not illustrated in FIG. 2. Instead, an application flap 212 is provided, through which the sample 112 can be introduced into the interior of the housing 210 in order to be positioned there in the beam path of the excitation light beam 122. By way of example, corresponding mounts can be provided for this purpose in the housing 210. Instead of a flap, it is also possible to provide any other type of closure desired, for example a slide, an insert or a similar type of closure.

Furthermore, in the arrangement in accordance with FIG. 2, two detectors 128, 130 are again provided, for the function of which reference can be made to the description regarding FIG. 1.

Furthermore, the device 110 in accordance with the exemplary embodiment in FIG. 2 has a control device 214, which can comprise for example a microcomputer and/or further electronic components and which serves for driving the light-emitting diode array 114 and also for reading from the detectors 128 and 130. The device 110 can furthermore comprise indicating elements 216 (for example one or more displays and/or optical indicators) and also operating elements 218. Furthermore, the device 110 in the exemplary embodiment in accordance with FIG. 2 comprises an interface 220 for a (wireless and/or wire-based) data exchange with other units, for example one or more computers.

FIG. 3 illustrates an alternative configuration of the device 110. While the devices in FIGS. 1 and 2 are suitable for transmission, absorption, fluorescence and phosphorescence measurements, for example, the device 110 in the exemplary embodiment in FIG. 3 is essentially suitable for reflection measurements. For this purpose, a sample could again be introduced into the housing 210, the reflection properties of said sample being measured in an arrangement similar to FIG. 1 or FIG. 2. The embodiment variant in FIG. 3 is configured, however, in such a way that here the housing 210 has an opening 310. The device 110, which can again be configured as a handheld unit from the standpoint of the housing dimensions, can be pressed or laid with said opening 310 for example onto a sample (not illustrated in FIG. 3), for example in such a way that a surface region of the sample that is to be examined is positioned in the region of the opening 310.

A light-emitting diode array 114 is again provided, which is driven by a control device 214 and which applies an excitation light beam 122 to the sample surface. The device 110 furthermore has a reflection detector 312, which picks up detection light reflected from the sample in the form of reflection light 314. In this case, a screen 316 can preferably be provided between light-emitting diode array 114 and reflection detector 312, said screen preventing excitation light 122 from passing directly from the light-emitting diode array 114 into the detector 312. The reflection signal provided by the reflection detector 312 is once again communicated to the control device 214 for evaluation. Indicating elements 216 and operating elements 218 for operating the device 110 are once again provided.

The exemplary embodiment of the device as illustrated in FIG. 3 symbolically illustrates a further variant for data exchange between the device 110 and further units such as, for example, a central server and/or another computer. For this purpose, the device 110, as an alternative or in addition to an interface 220, has a mobile data transmission device 318. In this way, data can be exchanged via a standardized mobile radio network. As an alternative to a mobile data transmission device 318 integrated into the device 110, however, a variant would also be conceivable in which, by way of example, the device 118 is connected via an interface 220 to a further mobile data transmission unit, for example a mobile telephone, in order then to utilize said mobile telephone for data exchange.

An exemplary embodiment of an excitation light source 410 is illustrated in plan view in FIG. 4. The excitation light source 410 can be used as a light source for generating the excitation light beam 122 for example in the devices 110 illustrated in FIGS. 1 to 3.

The excitation light source 410 comprises a baseplate 412, which can be configured for example as a round aluminium disc having two holes 414. A Peltier element (not illustrated in FIG. 4) can also be accommodated in the baseplate 412 in order to regulate the temperature of the excitation light source. By way of example, said Peltier element can be accommodated in a depression on the rear side of the baseplate 412 or be adhesively bonded onto said baseplate 412 by means of a thermally conductive adhesive.

The light-emitting diode array 114 already described in FIG. 1 is accommodated, for example by adhesive bonding, on the baseplate 412 of the excitation light source 410. The configuration of said light-emitting diode array 114 is explained in more detail below with reference to FIG. 5.

Furthermore, leads 416 are accommodated on the baseplate 412, and can be isolated from the aluminium baseplate 412 for example by an insulating intermediate carrier (not illustrated in FIG. 4). By way of example, a polyimide film can be used as the intermediate carrier on which the leads 416 are applied (for example in a thick-film method), via which the light-emitting diode array 114 can be supplied with current and driven. An insulating lacquer or an insulating powder coating as intermediate carrier or as insulation layer between the leads 416 and the aluminium baseplate 412 can also be used. The light-emitting diode array 114 can be adhesively bonded for example on the baseplate 412 and/or be fixed there for example by a force-locking method (for example a clamping method). The leads 416 are in turn connected to electrodes of the light-emitting diode array 114, for which purpose for example a wire bonding method can be used.

The leads 416, finally, are contact-connected by a plug connector 418, to which can be connected (coming from below in FIG. 4) a plug with a ribbon cable. The plug connector 418 can for example likewise be screwed or adhesively bonded on the baseplate 412.

In this way, by means of the arrangement shown in FIG. 4 it is possible to construct a compact, robust, largely vibration-insensitive and tuneable excitation light source 410 which can be used in a multiplicity of devices 110 in which a tuneable excitation light source of this type is required.

FIG. 5 shows an enlarged illustration of the light-emitting diode array 114. In this exemplary embodiment, this light-emitting diode array 114 comprises three individual monolithic light-emitting diode chips 420, 422, 424. In this case, the first chip 420 comprises nine individual light-emitting diodes 426, the second chip 422 comprises six individual light-emitting diodes 426 and the third chip 424 comprises three light-emitting diodes 426 of this type. In this case, the light-emitting diodes 426 can each be discerned as square areas having different electrode contacts 428, the electrode contacts being shown dark in the illustration in FIG. 5. These electrode contacts 428 are electrically contact-connected for example by means of a wire bonding method.

In this case, the individual light-emitting diodes 426 are each produced on a common carrier 430 of each of the chips 420, 422, 424 in such a way that they have different emission characteristics (see below, FIG. 6). The individual electrode contacts 428 can be connected to the leads 416 (see FIG. 4) by wire bonding, for example. For this purpose, bonding pads can also be provided on the individual carriers 430, at which bonding pads bonding locations can be arranged.

In this case, in FIG. 5 the three light-emitting diode chips 420, 422 and 424 are arranged in such a way that the entire light-emitting diode array 114 has a width B of 3.4 mm, and a height H of 1.6 mm. The light-emitting diode array 114 has a pitch (for example centre to centre distance between adjacent light-emitting diodes 426) of approximately 600 μm. In this case, approximately a quarter of the total area is filled by the active areas of the light-emitting diodes 426, and the rest of the surface area is interspace. Consequently, in this exemplary embodiment, the individual light-emitting diodes 426 are at a distance of approximately 300 μm from the respectively adjacent light-emitting diode 426. Arrangements other than the arrangement shown in FIG. 5 are also conceivable, however, for example arrangements in which the entire light-emitting diode array 114 is configured as an individual, monolithic chip, with an individual common carrier 430. Details of the light-emitting diode production of monolithic arrays are known to the person skilled in the art of semiconductor technology. The light-emitting diode array 114 having the three individual light-emitting diode chips 420, 422 and 424 that is illustrated in FIG. 5 was produced by contract manufacture by EPIGAP Optoelektronik GmbH in Berlin, Germany, and comprises for example light-emitting diodes comprising AlGaAs/AlGaAs and/or AlInGaP/GaP and/or AlInGaP/GaAs and/or AlGaAs/GaAl As and/or InGaN/Al₂O₃, as semiconductor materials.

FIG. 6 illustrates the individual spectra of the eighteen light-emitting diodes 426 of the light-emitting diode array 114 in accordance with FIG. 5. Here in each case the wavelength λ is plotted on the abscissa and the intensity Φ (normalized to 1) in arbitrary units is plotted on the ordinate.

It can be seen that the spectra of the light-emitting diodes 426 of the light-emitting diode array 114 cover a spectral range of between approximately 450 nm and approximately 850 nm. In this case, the respective maxima 610 of the spectra are not distributed equidistantly. Overall, however, it can be seen that the spectra of the individual light-emitting diodes 426 are very narrowband, such that the full width at half maximum (such a full width at half maximum 612 is plotted by way of example for the light-emitting diode 426 having the longest wavelength in FIG. 6) does not exceed a value of 30 nm for any light-emitting diode 426. Typical full widths at half maximum even lie below 30 nm, such that 20 nm can preferably be chosen as an upper limit with respect to this full width at half maximum.

In this case, the full width at half maximum (FWHM) should be understood to mean the spectral width of the emission curve at half the intensity value at the maximum 610.

It can easily be seen on the basis of FIG. 6 that virtually any desired spectrum within the visible spectral range can easily be generated by an intensity regulation of the emission of the individual light-emitting diodes 426. This driving can comprise a digital driving, that is to say a pure on/off switching, but can also comprise intermediate values between a maximum brightness and a switched-off state, for example in the form of a digital grey level regulation (for example an 8- or 16-bit driving of the brightnesses) or a pure analogue driving. In this way, the intensities Φ of the individual light-emitting diodes 426 can be mixed virtually as desired.

FIG. 7 illustrates a basic schematic diagram of a device 110 for determining at least one optical property of a sample 112, which substantially corresponds to the construction in accordance with FIG. 1 or FIG. 2. On the basis of this basic schematic diagram, an explanation will be given of a development of the invention in which, by virtue of a suitable modulation of the intensities of the individual light-emitting diodes 426, an excitation-side monochromator can be dispensed with, wherein a complete spectrum of a sample 112 can nevertheless be recorded, preferably virtually simultaneously. In this case, only the fluorescence light 136 is considered by way of example in FIG. 7, but other configurations are also possible, for example (as an alternative or in addition) a transmission or absorption spectrum, a phosphorescence spectrum, a reflection spectrum or other types of spectroscopy. The principle illustrated in FIG. 7 should be modified analogously in these cases.

FIG. 7 shows an arrangement which once again comprises a light-emitting diode array 114, for example the light-emitting diode array 114 illustrated in FIG. 5, wherein the individual light-emitting diodes 426 of said light-emitting diode array 114 can be driven individually. However, the principle of the measurement described below can be extended, independently of the light-emitting diode array 114, to other types of excitation light sources which comprise spectrally different excitation light sources which can be driven independently of one another. Accordingly, reference should be made to FIG. 9, which illustrates a generalized flowchart of a method according to the invention, which can also be carried out independently of the presence of a light-emitting diode array 114, that is to say with any desired excitation light source having independently controllable, spectrally different individual excitation light sources. Instead of or in addition to the method described below with fluorescence detection, it is, of course, also possible analogously to evaluate other optical properties, for example reflection signals, scattering signals, phosphorescence signals, transmission signals and/or other types of optical signals.

The individual method steps in FIG. 9 can be supplemented by further method steps that are not illustrated. Furthermore, the order of the method steps that is illustrated in FIG. 9 is preferred but not mandatory. Furthermore, individual or a plurality of method steps can also be carried out repeatedly. The method in FIG. 9 and the basic construction in FIG. 7 will be elucidated jointly below.

For the construction of the device 110 in FIG. 7, reference can largely be made to the construction in accordance with FIG. 1. However, the construction is extended relative to FIG. 1 to the effect that here a two-beam construction was realized optionally and by way of example. Thus, a reference beam 710 is tapped off from the excitation light beam 122 (for example by means of a partly transmissive mirror, which is not illustrated, or by means of some other optical device). The intensity of said reference beam 710 is monitored or picked up by a reference detector 712.

The device 110 in accordance with the exemplary embodiment in FIG. 7 has a multiplexing device 714 and a demodulation device 716. Multiplexing device 714 and demodulation device 716 here in each case share a series of local oscillators 718, which are designated by “LO” in FIG. 7. In accordance with the number n of light-emitting diodes 426 (or some other type of individually driveable light sources), n local oscillators 718 are present.

The local oscillators 718 each generate clock signals 720, for example in the form of sinusoidal, cosinusoidal, rectangular or different periodic signals each having an individual frequency f1 to fn for each light-emitting diode 426 (or other light source). In the context of the multiplexing device 714, said clock signal 720 is communicated to current sources 722 or generally driving systems which supply the individual light-emitting diodes 426 with current. In this way, an individual light-emitting diode current 724 is generated for each of the light-emitting diodes 426, the respective assigned light-emitting diode 426 being driven with said current. In this way, the intensity Φ of the individual light-emitting diodes 426 can be modulated with an individual frequency f1 to fn, such that these frequency components are contained in the excitation light 122. This step of modulation of the individual light sources f1 to fn is designated symbolically by the reference numeral 910 in the schematic method sequence in FIG. 9. In this way, the excitation light beam 122 can be modulated by the modulation 910 of the individual light sources in such a way that it is composed of differently modulated spectral components. Generally, the following spectrum can thus be generated:

$$Φ ( λ , t ) = {\sum }_{i} ( {Φ}_{i , 0} ( λ ) + {Φ}_{i , 1} ( λ ) \cdot cos ( 2 \cdot π \cdot fi \cdot t + ϕ i ) ) .$$

In this case, Φ(λ,t) designates the intensity in each case as a function of the wavelength and time, which is combined as a sum of the intensities of the individual light sources. This sum comprises a constant offset component Φ_{i,O}(λ) in each case for each individual light source (the running variable in this case runs from 1 to n, that is to say over all the light sources). Furthermore, the sum comprises for each individual light source a modulated component which in each case comprises a prefactor Φ_{i,1}(λ), which is modulated cosinusoidally in this exemplary embodiment, with an individual modulation frequency fi for each individual light source. Said modulation frequency is generated by the local oscillators 718, as described above. The modulation can be individually phase-shifted in each case with a phase Φᵢ for each of the individual light sources. In this way, by suitably setting the variables Φ_{i,1}, fi and Φⱼ in the context of the available spectra (cf. FIG. 6) of the individual light sources (for example of the individual light-emitting diodes 426), in method step 910, it is possible to generate an excitation light beam 122 with a desired spectral design with individually modulated individual light sources. In this case, an infinite number of individual light sources would ideally be used, each having an infinitely narrow emission spectrum, such that a continuous arbitrary spectrum can be established, with in each case individually modulated individual frequencies.

As described above, the reference beam 710 is split off from the excitation light beam 122. The excitation light beam 122 correspondingly generates a fluorescence light 136 in the sample 112, said fluorescence light in turn having individual modulations in response to the modulation in step 910. Said fluorescence light is picked up in method step 912, for example by means of the detector 128 in the arrangement in accordance with FIG. 7. If other spectroscopy arrangements are used, then for example transmission light, reflection light or other light would be picked up in said method step 910. The further method steps should then be carried out analogously.

In parallel (or else with a temporal offset), in method step 914, which is an optional method step, the reference beam 710 is detected, for example by the reference detector 712.

The signals generated by the two detectors 128 and 712 (wherein it is also possible for more detectors to be provided) contain, in accordance with the modulation carried out in method step 910, once again frequency components having the frequencies f1 to fn. In the fluorescence light 136 these frequency components in each case correspond to the response of the sample 112 to the spectrum of the corresponding modulated light source. By way of example, the fluorescence response to the incidence of the light from the first light-emitting diode 426 (LED1), which was modulated with the frequency f1, is likewise contained with the frequency f1 in the fluorescence light beam 136. Said fluorescence response can therefore be recovered by means of a suitable frequency analysis of the fluorescence light in the frequency domain, such that the fluorescence responses to each excitation light source can be determined temporally in parallel.

For this purpose, in method step 916, the signal of the fluorescence detector 128 is split and mixed separately with each of the clock signals 720 of the individual local oscillators 718 in frequency mixers 726. This gives rise to mixed signals, which are subsequently (method step 918 in FIG. 9) filtered by means of suitable filters (730 in FIG. 7). By way of example, said filters 730 can have low-pass filters and/or bandpass filters which are in each case tuned to the individual modulation frequency f1 to fn for each of the mixed signals 728. In this way it is possible to generate raw signals S1 to Sn, which are identified by reference numeral 732 in FIG. 7 and which are in each case response signals to the incidence of radiation of the individual light-emitting diodes LED1 to LEDn.

The method steps which are described in method steps 916 to 918 and which are carried out in the demodulation device 716, for example, are standard methods in radio-frequency technology which are used for example in the context of lock-in methods. Accordingly, modifications of the method illustrated and/or of the arrangement illustrated are possible and known to the person skilled in the art.

In an analogous manner, the reference light picked up in method step 914 can (optionally) be demodulated. In this case (method step 920 in FIG. 9) this reference signal can in turn be split into n individual signals which are then mixed in each case with the clock signals 720 in frequency mixers 734. Afterwards, in method step 922, analogously to the above description of method step 918, a filtering operation is effected in filters 936, said filtering operation once again being adapted to the individual modulation frequency. Individual reference signals 738 are generated in this way.

FIG. 9 furthermore illustrates how the raw signals 732 and the reference signals 738 which were obtained by means of the method described above and for example by means of the device 110 illustrated in FIG. 7 can be processed further in order to generate a fluorescence spectrum of the sample 112. It should be pointed out that the method steps described below are optional, however, and that other types of further processing of the raw signals 732 are also possible. The signal processing can be effected for example in a control device 214 such as is illustrated for example in FIGS. 2 and 3. Said control device 214 can also wholly or partly comprise the multiplexing device 714 and/or the demodulation device 716, for example in the form of discrete electrical components and/or wholly or partially in the form of computer-implemented software modules.

In method step 924, a quotient is formed in each case from a raw signal Si 732 (where i assumes a value of between 1 and n) and an assigned reference signal R1738. The result of this quotient formation is a set of n relative fluorescences Fi. The latter can be plotted, in a method step 926, for example, against the corresponding wavelength λi of the light source (for example of the respective light-emitting diode 426). The result of such plotting is illustrated in FIG. 8. By way of example, the wavelength VI can be in each case the wavelength of the maxima 610 of the individual light-emitting diodes. This results in a spectrum which is composed of individual points and which is illustrated schematically in FIG. 8. It can also be discerned from this that a largest possible number of different wavelengths λi is advantageous since in this way a continuous spectrum can finally be assembled with an increase in the number of light sources.

The signal obtained in this way and/or already the raw signals 732 can subsequently optionally be processed further and evaluated in method step 928. This evaluation 928, which can be effected for example once again in the control device 214 and/or in an external computer, can comprise for example a pattern recognition in the spectrum in accordance with FIG. 8. By way of example, the spectrum obtained in this way can be correlated with a known reference spectrum. For example a reference spectrum of a marker substance contained in a branded product. If a match (for example a match which lies above a predetermined threshold) is ascertained, then it is deduced that the marker substance is contained in the sample 112. In this way for example branded products, such as for example mineral oils from a specific manufacturer, can be identified and distinguished from counterfeit products. In this way, the method illustrated in FIG. 9 and a device 110 according to the invention, for example the device in accordance with FIGS. 2 and/or 3, can be utilized in order to implement brand protection and to identify counterfeit products rapidly and reliably on site.

Finally, FIG. 10 illustrates a variant of the device 110 illustrated in FIG. 7. This method variant is based on the idea that the device 110 in accordance with FIG. 7 generally requires one or more lock-in amplifiers with frequency mixers 726 for the analysis of the signals, which in principle requires a comparatively high outlay. This outlay can be reduced if for example integrated circuits comprising the required components as integrated components are used. By contrast, FIG. 10 shows a variant of the device 110 which can operate for example with finished electronic components.

The device 110 in accordance with FIG. 10 is firstly constructed largely analogously to that illustrated in FIG. 7, such that for most of the components reference can be made to the above description of FIG. 7. In contrast to FIG. 7, however, in FIG. 10 the at least one signal provided by the at least one detector 128 is firstly converted into one or more digital signals in one or more analogue-to-digital converters 1010. The output signal or signals of said analogue-to-digital converter 1010 are communicated to a frequency analyser 1012. In this exemplary embodiment, said frequency analyser 1012 wholly or partly performs the function of the demodulation device 716. Here the at least one signal of the detector 128 is analysed, for example by means of a fast Fourier analysis (FFT), such that for example the partial signals lying within the frequency ranges f1 to fn can be determined separately in each case. These signals are then output as signals S1 to Sn (designated as “raw signals” 732 in FIG. 10). These raw signals 732 can subsequently be processed further, for example by means of the method described above with reference to FIG. 8, for example using the reference signals 738, in particular for creating a spectrum similar to the spectrum illustrated in FIG. 8.

Furthermore, it should also be pointed out that the variant of the device 110 as illustrated in FIG. 10 can also be modified even further to the effect that the reference signals 738 can also be generated by means of a frequency analyser instead of frequency mixers 734. For this purpose, the at least one signal determined by the at least one reference detector 112 could once again be converted into at least one digital signal for example by means of an analogue-to-digital converter and then subsequently be subjected to a frequency analysis (for example once again a Fourier transformation) in a frequency analyser. Here, too, the further processing of these reference signals R1 to Rn 738 would for example again be analogous to the above description of FIG. 8.

A device variant in which only the reference signals 738 are generated by a frequency analyser, whereas the raw signals 732 are generated analogously to FIG. 7, is also conceivable.

It would also be conceivable for the clock signals 720 of the local oscillators 718 to be made available to the frequency analyser or analysers 1012 used for the generation of the raw signal 732 and/or for the generation of the reference signals 738, in order to further improve the frequency analysis.

For the test of the device described above in one of the possible embodiments, various spectral measurements were carried out on known substances. FIG. 11 illustrates by way of example a measurement result of such a measurement, which was obtained using a measurement set-up analogous to the device illustrated in FIG. 2. In this case, a measurement and evaluation scheme analogous to the embodiment illustrated in FIG. 10 was used in the context of this measurement example, such that with regard to the details of this measurement, reference can be made to the descriptions of said FIGS. 2 and 10.

In the exemplary embodiment illustrated, the device 110 illustrated in FIG. 2 was used to detect an extinction spectrum of a mineral oil marked with a marker substance in a round sample vessel. Commercial diesel oil from Aral was used here as mineral oil. An anthraquinone dye having the following structural formula:

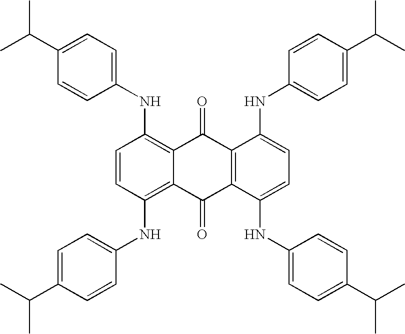

was admixed with said diesel oil as a marker substance.

The concentration of the marker substance was 500 ppb (in mass units) in the mineral oil. The marker substance was dissolved in the mineral oil and filled into a sample vial made of clear glass (borosilicate glass) having a diameter of 17 mm and a height of 63 mm (capacity approximately 8 ml). The sample vial was introduced as sample 112 (see FIG. 1) into the device 110 illustrated in FIG. 2 and was irradiated by the excitation light beam 122. In this exemplary embodiment, only the transmission light 132 was detected by the detector 130. In this respect, the arrangement used deviated from the device 110 according to FIG. 10 in so far as FIG. 10 illustrates the case of a measurement of fluorescence light 136, whereas in the present exemplary embodiment, instead of the fluorescence light 136, the transmission light 132 was detected, digitized by means of an ADC 1010 and analysed by means of a frequency analyser 1012. The intensities 11 to 118 transmitted through the sample vial, said intensities corresponding to the signals S1 to Sn in FIG. 10, were measured in this way. The measurement duration was only approximately 5 seconds. Afterwards, the sample vial was removed from the device 110 and the intensities then falling onto the detector 130 were measured in 101 to 1018, corresponding to the signals R1 to Rn in FIG. 10. This shows that (see FIG. 7) the reference light beam 710 need not necessarily be a beam tapped off from the excitation light beam 122, but rather can also be wholly or partly identical with the latter, for example by simply removing the sample 112. Moreover, the reference detector 712 in FIG. 7 need not necessarily be embodied separately from the detectors 128, 130 (see FIG. 2), but rather can also be wholly or partly identical with one or more of said detectors 128, 130.

The graphic representation illustrated in FIG. 11 shows the extinction ε, which is calculated according to the stipulation εi=log (10i/li). This extinction is plotted as a function of the wavelength λ, in nm in FIG. 11. In this case, the individual measurement points of the individual light-emitting diodes 426 are illustrated as square boxes in FIG. 11. The solid line represents a polynomial fit function that was matched to the 18 measurement points recorded.

The measurement curve illustrated in FIG. 11 shows firstly the range of the extinction of the mineral oil in a range below approximately 600 nm. This extinction decreases greatly as the wavelength increases. This extinction is followed by the characteristic extinction of the marker substance in a range from approximately 650 to 850 nm. This simple exemplary embodiment shows that, by means of the device 110 illustrated in FIG. 2, characteristic spectra of marker substances can be recorded in a simple and rapid manner without requiring time-consuming and technically complex tuning of an excitation light source. In this way, it is thus possible for example to realize simple handheld units which supply information about a sample, such as the marked mineral oil in the present case, on site in a matter of seconds. Such devices thus represent a considerable stride towards effectively combating product piracy, for example, since, in this way, characteristic markings which, however, are generally at least largely invisible to the human eye and which are attached only to original products can be sought for example rapidly and simply on site.

### LIST OF REFERENCE SYMBOLS

110 Device for determining at least one optical property of a sample
112 Sample
114 Light-emitting diode array
116 Aluminium carrier
118 Peltier element
120 Monitor
122 Excitation light beam
124 Cuvette
126 Flattened portion
128 Detector
130 Detector
132 Transmission light (detection light)
134 Planastigmatic correction
136 Fluorescence light (detection light)
138 Filter
210 Housing
212 Application flap
214 Control device
216 Indicating element
218 Operating element
220 Interface
310 Opening
312 Reflection detector
314 Reflection light (detection light)
316 Screen
318 Mobile data transmission device
410 Excitation light source
412 Baseplate
914 Picking up reference light
414 Holes
416 Leads
418 Plug connector
420 Light-emitting diode chip
422 Light-emitting diode chip
424 Light-emitting diode chip
426 Light-emitting diodes
428 Electrode contacts
430 Carrier
610 Maxima
612 Full width at half maximum, FWHM
710 Reference beam
712 Reference detector
716 Demodulation device
718 Local oscillators
720 Clock signals
722 Current sources
724 Light-emitting diode current
726 Frequency mixer
728 Mixed signal
730 Filter
732 Raw signals
734 Frequency mixer
736 Filter
738 Reference signal
910 Modulating the intensity of the individual light sources
912 Picking up fluorescence light
1010 Analogue-to-digital converter
916 Mixing fluorescence signal with modulation frequency
918 Filtering
920 Mixing reference signal with modulation frequency
922 Filtering
924 Forming quotient Si/Ri
926 Plotting quotient Si/Ri=Fi against wavelength λi
928 Evaluation
1012 Frequency analyser

1-36. (canceled)

37. A device for determining at least one optical property of a sample, wherein the device comprises a tuneable excitation light source for applying excitation light to the sample, wherein the device furthermore comprises a detector for detecting detection light emerging from the sample, wherein the excitation light source comprises a light-emitting diode array, wherein the light-emitting diode array is configured at least partly as a monolithic light-emitting diode array, wherein the monolithic light-emitting diode array comprises at least three light-emitting diodes each having different emission spectrums, wherein the light-emitting diodes of the light-emitting diode array lie so close together that if all the light-emitting diodes of the light-emitting diode array are switched on, essentially a mixed light beam arises, wherein the individual emissions of the light-emitting diodes of the light-emitting diode array are essentially combined to form a common beam of excitation light.

38. The device according to claim 37, wherein the light-emitting diode have an average spacing which is less than one millimetre.

39. The device according to claim 37, wherein the light-emitting diode array comprises at least one of the following light-emitting diode arrays: an inorganic monolithic light-emitting diode array having an inorganic semiconductor chip; an organic monolithic light-emitting diode array having a thin-film transistor circuit integrated on a carrier of the light-emitting diode array.

40. The device according to claim 37, wherein the light-emitting diode array comprises at least ten light-emitting diodes.

41. The device according to claim 37, furthermore comprising a temperature-regulating device, wherein the temperature-regulating device is designed to regulate the temperature of the light-emitting diode array.

42. The device according to claim 41, wherein the temperature-regulating device furthermore comprises a regulation device.

43. The device according to claim 37, wherein the light-emitting diodes of the light-emitting diode array each have a spectral width, wherein the spectral width does not exceed a value of 30 nm.

44. The device according to claim 37, wherein the light-emitting diodes of the light-emitting diode array cover a spectral range of 450 nm to 850 nm.

45. The device according to claim 37, wherein the detector comprises a detector array having at least two individual detectors, wherein the detector array comprises a monolithic photodiode array.

46. The device according to claim 37, wherein the detector has at least one luminescence light detector arranged non-collinearly with the excitation light.

47. The device according to claim 37, wherein the detector has at least one transmission light detector arranged collinearly with the excitation light.

48. The device according to claim 37, wherein the detector has at least one reflection light detector for detecting reflection light reflected from the sample.

49. The device according to claim 37, furthermore having a control device, wherein the control device is designed to generate excitation light having predetermined spectral properties by driving the individual light-emitting diodes of the light-emitting diode array.

50. The device according to claim 49, wherein the control device comprises a multiplexing device, wherein the multiplexing device is designed to modulate at least two of the light-emitting diodes of the light-emitting diode array with different modulation frequencies.

51. The device according to claim 50, wherein the control device furthermore has a demodulation device, wherein the demodulation device is designed to demodulate detection light phase-sensitively and/or frequency-sensitively and to assign it in each case to one of the modulated light-emitting diodes.

52. The device according to claim 51, wherein the device is designed to record an excitation spectrum of the sample, wherein a plurality of light-emitting diodes of the light-emitting diode array are operated simultaneously, wherein the excitation light contains differently modulated portions of the individual light-emitting diodes, wherein the detection light is demodulated and assigned to the individual light-emitting diodes, and wherein a corresponding excitation spectrum is generated.

53. The device according to claim 37, furthermore comprising a cuvette for receiving a liquid sample, wherein the cuvette has at least partly a circular cross section.

54. The device according to claim 37, wherein the device is configured as a two-channel spectrometer, wherein the device is designed to simultaneously pick up at least one optical property of the sample and a reference beam.

55. The device according to claim 54, wherein at least one optical property of a reference sample is determined.

56. The device according to claim 37, wherein the device is configured as a mobile handheld unit.

57. The device according to claim 56, wherein the mobile handheld unit furthermore has an interface for connecting the mobile handheld unit to a mobile data transmission unit or a computer.

58. A method for checking whether a product is a branded product or a counterfeit of a branded product, wherein the branded product has at least one characteristic optical property, wherein a device according to claim 37 is used, wherein the device is used to test whether the product has the characteristic optical property.

59. A method according to claim 58, wherein the branded product comprises a mineral oil product.
